(19) United States
(12) Patent Application Publication
(10) Pub. No.: US 2010/0019774 A1
(43) Pub. Date: Jan. 28, 2010

(54) ISOLATION CELL WITH TEST MODE

(75) Inventors: Cheng-Chi WU, Nantou (TW); Yu-Wen TSAI, Hsinchu (TW); Shang-Chih HSIEH, Taoyuan (TW); Chun-Sung SU, Chiayi (TW)

Correspondence Address: WPAT, PC;INTELLECTUAL PROPERTY ATTORNEYS, 7225 BEVERLY ST., ANNANDALE, VA, 22003, US

(73) Assignee: FARADAY TECHNOLOGY CORPORATION, Hsinchu (TW)

(21) Appl. No.: 12/178,985

(22) Filed: Jul. 24, 2008

(51) Int. Cl. G01R 31/02

(52) U.S. Cl. 324/537

(57) ABSTRACT

An isolation cell having a test mode, connected between a first block and a second block, wherein the first block can operate in either a power-up mode or a power-down mode, comprises: an input terminal for receiving an input signal that is derived from the first block; an output terminal for outputting an output signal to the second block; a normal-sleep terminal for determining the isolation cell is operated in the power-up mode or in the power-down mode, and the logic level of the normal-sleep terminal is determined by the operation mode of the first block; and, a DFT-sleep terminal is for overwriting the logic level of the normal-sleep terminal when the isolation cell is in the test mode.

### FIELD OF THE INVENTION

The present invention relates to an isolation cell, and more particularly to an isolation cell capable of being tested when operated in a power-down mode.

### BACKGROUND OF THE INVENTION

In IC design field, there are often scenarios in which a first portion of a circuit can be operated in a power-down mode (i.e., no supply of power), while the other portion (the second portion) of the circuit is always operated in a power-up mode. For example, for reducing power consumption, the first portion is operated in the power-down mode when the first portion is expected not to be used for a short duration, while the second portion continues to operate. In other words, there should be isolation cells in the circuit to maintain data for preventing input floating when the first portion in the power-down mode is back to the power-up mode for continuity of operation.

One recognized problem with concurrent circuit is that the first portion may provide an output signal to the second portion in the power-up mode. In such a configuration, the output signal can be in an undriven state (floating) and may cause the second portion to malfunction if the first portion is changed to the power-down mode.

FIG. 1 is a block diagram showing a circuit with a block having both the power-up mode and power-down mode. The circuit comprises a power mode control circuit 11, a power switching unit 13, a power gated functional block 15, and an always-on functional block 17. In the circuit, the power mode control unit 11 receives the control signal to control power switching unit 13. In response to the control of the power mode control unit 11, the power switching unit 13 can provide a source voltage (Vdd) to the power gated functional block 15 for operating in power-up mode. Furthermore, the power switching unit 13 can stop providing the source voltage (Vdd) to the power gated functional block 15 for operating in power-down mode.

As shown in FIG. 1, the input signal (A) can be propagated to the power gated functional block 15 for processing, and the processed signal (N1) can be transmitted to the always-on functional block 17, which is always powered. Obviously, when the power gated functional block 15 is operated in the power-down mode, the processed signal (N1), derived from the power gate functional block 15, will be an undriven state (floating).

An approach to avoiding such undriven states is to provide an isolation cell, which maintains at a specific logic level to the input terminal of the always on functional block when/after the power gated functional block transitions from the power-down mode to power-up mode. FIG. 2 is a block diagram showing a circuit including an isolation cell. The circuit comprises: a power mode control unit 21, a power switching unit 23, a power gated functional block 25, an always-on functional block 27, and an isolation cell 29.

In the circuit, the power mode control unit 21 receives the control signal and generates the sleep signal to control power switching unit 23 and the isolation cell 29. For example, when the sleep signal is at a first logic level, it enters the power-up mode. In power-up mode, the power switching unit 23 can provide a source voltage (Vdd) to the power gated functional block 25. Also, the isolation cell 29 functions as a buffer. In other words, the input signal (A) can be propagated to the power gated functional block 25 for processing, and the processed signal (N1) can be transmitted to the input terminal (I) of the isolation cell 29 and the output terminal (O) of the isolation cell 29 can output the processed signal (N1) to the always-on functional block 27.

Alternatively, when the sleep signal is at a second logic level, it enters the power-down mode. In power-down mode, the power switching unit 23 stops providing the source voltage (Vdd) to the power gated functional block 25. Also, during the period of power-down mode, the isolation cell 29 maintains a specific signal to the input terminal of the always-on functional block 27. In this way, the always-on functional block 27 can operate normally when the power gated functional block 25 is in power-down mode. Furthermore, the isolation cell 29 is designed to output a specified logic level to the input terminal of the always-on functional block 27. There are three types of isolation cell, which is dependent on the specific logic level of the isolation cell. For example, the isolation cell 29 can be designed to output a logic high to the input terminal of the always-on functional block 27; the isolation cell 29 can be designed to output a logic low to the input terminal of the always-on functional block 27; or, the isolation cell 29 can be designed to output a logic level same as the previous logic level to the input terminal of the always-on functional block 27.

Before an Integrated Circuit (IC) including an isolation cell releases to market, the IC must be tested first. Traditional functional IC testing exercises the Device Under Test (DUT) in its normal operational mode. That is, by applying values to the input terminals of the device and measuring the results, it uses the normal operation of the IC to put the internal device logic into states that allow particular faults to be detected.

There is wide variation in how tests are organized and applied to the device in traditional test. In general terms, to perform a test the DUT is clocked through multiple cycles, with a specified pattern of inputs applied and outputs measured at each cycle. A test program consists of a sequence of these tests. The tests do not overlap one another; however, there may be complex interdependencies between tests (one test relying on a previous test having placed the DUT in a particular state).

IC test systems today are designed to perform these sorts of tests. (By test system, it means the combination of a tester, which exercises the DUT, and the accompanying hardware and software system that has access to and control of the tester.) These testers employ an internal format to specify the test program. The details are specific to each test system, but all represent the data in cycle-based form, with force values (input value applied to the DUT) and expect values (output value expected from the DUT) for each cycle. Because of the differences in internal formats and tester capabilities, each test program is specific to a particular test system. Test programs are either coded with knowledge of the test system requirements, or are modified to conform to those requirements when translated from an interchange format into the internal format. When the test system applies the test program to the device under test, device faults are detected as mismatches between expect value and the values actually produced by the DUT. The test system reports these mismatches in terms of the failing cycle number and terminal name.

However, as IC complexity has increased, to current devices with 10-100 million gates, they have become increasingly difficult to test effectively or efficiently using traditional functional test. Using normal device operations, it can be a complex task to establish the logic level required detecting a particular fault, and it becomes increasingly difficult to determine the fault coverage of a test program. Moreover, the largely manual effort of creating the test program becomes prohibitively expensive.

Complex ICs are typically built out of components in a hierarchical structure, and many of these components are reused in multiple ICs. There is a benefit to being able to develop tests for these components that can also be reused, and this is typically not feasible with traditional functional test. There is also a benefit, when faults are detected, to be able to identify where in the hierarchy of components the fault occurred.

In response to these issues, design methodologies referred to as Design for Testability (DFT) have been developed to allow much of the test development process to be automated. A commonly used DFT approach is internal scan test. It relies on the addition of specialized test circuitry to the IC. In contrast to functional test, which exercises the device as a whole using its normal operating mode, scan test uses the test circuitry in a separate scan mode to set or examine the state of the IC (or part of the IC), thus bypassing the intractable task of performing these operations using the normal operating mode. Since the device state is accessible, scan tests can exercise circuitry locally. This allows tests to be generated automatically, and allows the automated isolation of faults detected by the tests.

The test circuitry added to the IC for scan test modifies the internal nodes of the device that retain state information from one cycle to the next, allowing these scan cell nodes to be linked together in a scan chain with its ends linked to a scan input and scan output pin. In scan mode, the scan chain functions as a shift register, allowing data values to be scanned into the scan cells at one end and out the other, one per cycle. The scan circuitry adds 10-15% to the circuitry of the IC. A typical configuration splits the scan cells among multiple scan chains. A greater number of chains reduce the number of cycles required to load and unload the IC state, but each chain requires connections to two pins. Depending on how this tradeoff is weighed, a typical configuration may contain 16-256 scan chains, with 200-2,000 scan cells per chain. The Scan Input and Scan Output normally share pins that serve a different purpose during normal device operation.

Conceptually, a scan test consists of a load phase, in which the scan chains are shifted multiple cycles in scan mode to set the state of the DUT, an exercise phase, consisting of one or more cycles in normal operational mode, and an unload phase, in which the scan chains are again shifted multiple cycles in scan mode to examine the state resulting from the exercise phase. An Automated Test Pattern Generation (ATPG) tool is used to automatically generate scan tests. A large number of scan tests are required to achieve high levels of fault coverage—a typical scan test program consists of 1,000-10,000 tests. Unlike traditional functional tests, scan tests have a highly consistent organization imposed by the ATPG tool, and, because each test resets the DUT state, there are no interdependencies between tests.

FIG. 3 is a block diagram showing the scan chain applying to a circuit having an isolation cell. When the circuit is in the scan mode, the scan input signal (test pattern) can be sequentially transmitted to the always-on functional block 27. Also, the scan output signal outputted by the always-on functional block 27 is the test result.

As mentioned above, the scan chain functions as a shift register, allowing data values to be scanned into the scan cells at one end and out the other, one per cycle. As known in the art, the source voltage (Vdd) in the testing circuit must be turned on when the Scan Chain is executed. That is to say, the power gated functional block 25 in FIG. 3 is not allowed to operate in power-down mode when Scan Chain is executed. It follows only the isolation cell operated in the power-up mode can be tested by the scan chain. If designer intends to test the isolation cell in the power-down mode by the scan chain, the designer should design a plurality of power domains and a power managing unit in the IC to further control different power domains in different modes. Therefore, developing an isolation cell, having a test mode and capable of being tested by the scan chain when the isolation cell is operated in the power-down mode, is the main purpose of the present invention.

### SUMMARY OF THE INVENTION

Therefore, without complicate circuit design in the isolation cell, the isolation cell's behavior in power-down mode can be tested by the scan chain, so as the testing quality is enhanced.

The present provides an isolation cell having a test mode, connected between a first block and a second block, wherein the first block can operate in either a power-up mode or a power-down mode, comprising: an input terminal for receiving an input signal that is derived from the first block; an output terminal for outputting an output signal to the second block; a normal-sleep terminal for determining the isolation cell is operated in the power-up mode or in the power-down mode, and the logic level of the normal-sleep terminal is determined by the operation mode of the first block; and, a DFT-sleep terminal is for overwriting the logic level of the normal-sleep terminal when the isolation cell is in the test mode.

Furthermore, the present invention provides an isolation cell having a test mode, connected between a first block and a second block, wherein the first block can operate in either a power-up mode and a power-down mode, comprising: an isolation unit having a sleep terminal, an input terminal, and an output terminal, wherein the sleep terminal is for determining the isolation unit is operated in the power-up mode or the power-down mode, the input terminal is for receiving an input signal which is derived from the first block, and the output terminal is for outputting an output signal to the second block; and an OR-gate having a normal-sleep input terminal, a DFT-sleep input terminal, and an OR-gate output terminal connected to the sleep terminal; wherein the normal-sleep terminal is at a first logic level if the first block is operated in the power-up mode; the normal-sleep terminal is at a second logic level if the first block is operated in the power-down mode; and the normal-sleep terminal is always at the first logic level and the first block is always operated in the power-up mode if the isolation cell is in the test mode.

### BRIEF DESCRIPTION OF THE DRAWINGS

The above objects and advantages of the present invention will become more readily apparent to those ordinarily skilled in the art after reviewing the following detailed description and accompanying drawings, in which:

FIG. 1 is a block diagram showing a circuit having both the power-up portions and power-down portions;

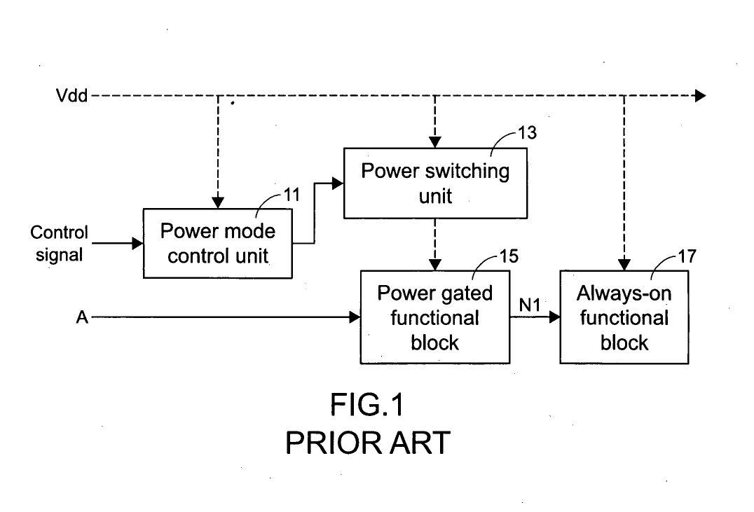

FIG. 2 is a block diagram showing a circuit including a prior-art isolation cell;

FIG. 3 is a block diagram showing the scan chain applying to a circuit having a prior-art isolation cell;

FIG. 4 is a block diagram showing the new isolation cell having a test mode of the present invention;

FIG. 5 is a block diagram showing the scan chain applying to a circuit having a new isolation cell of the present invention; and

FIG. 6 is a flow chart showing the steps of testing the new isolation cell of the present invention operated in power-up mode and power-down mode by using a scan chain.

### DETAILED DESCRIPTION OF PREFERRED EMBODIMENTS

The present invention discloses a new isolation cell having a test mode. When the new isolation cell is operated in the test mode and tested by the scan chain, the new isolation cell of the present invention can be switched between the power-up mode and power-down mode.

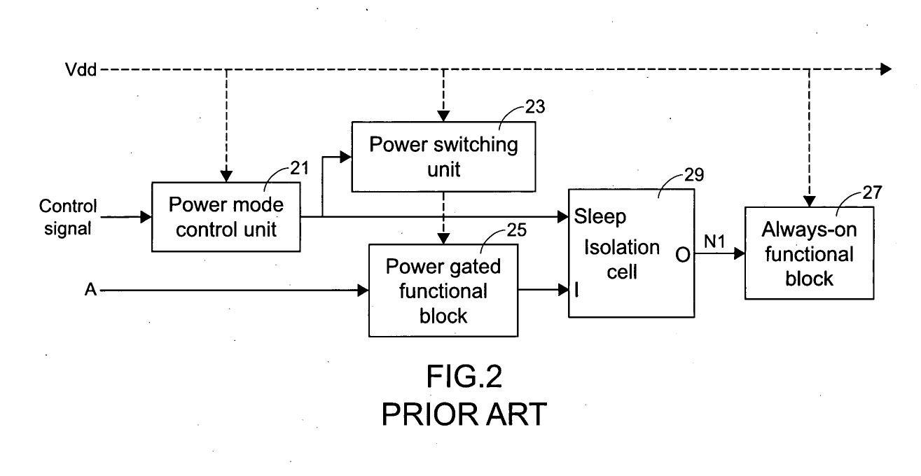

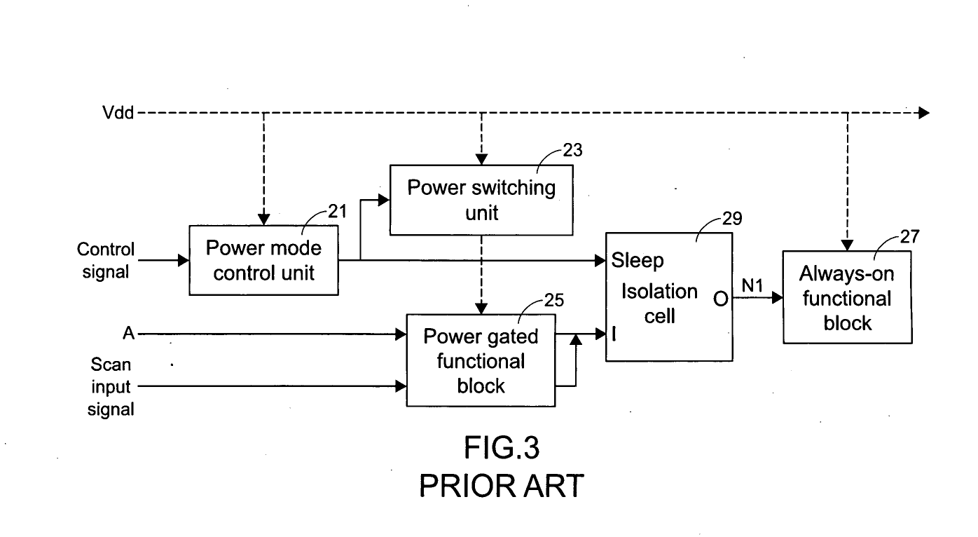

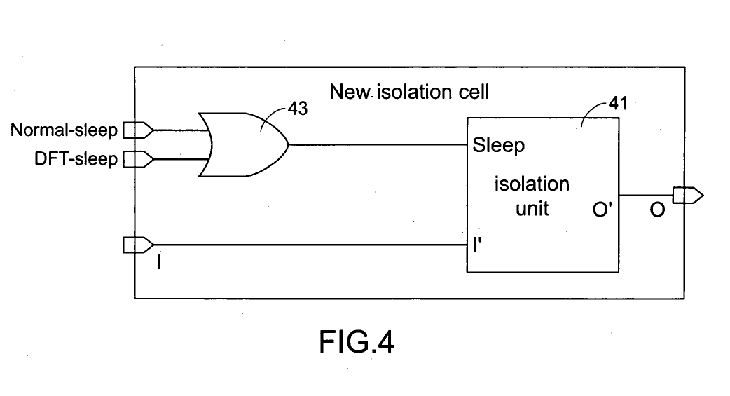

FIG. 4 is a block diagram showing the new isolation cell having a test mode of the present invention. The new isolation cell of the present invention consists of: an isolation unit 41, an OR-gate 43, a normal-sleep terminal, a DFT-sleep terminal, an input terminal I, and an output terminal O. In the new isolation cell of the present invention, the function of the isolation unit 41 is same as the conventional isolation cell as shown in FIG. 2 or FIG. 3. The isolation unit 41 includes an input terminal (I′) and an output terminal (O′) respectively connected to the input terminal (I) and the output terminal (O) of the new isolation cell. The normal-sleep terminal and the DFT-sleep terminal are respectively connected to two input terminals of the OR-gate 43; the output terminal of the OR-Gate 43 is connected to the sleep terminal of the isolation unit 41.

As mentioned above, when the scan chain is executed to the new isolation cell, the voltage source (Vdd) in a circuit is necessary to be turned on. According to the present invention, the new isolation cell includes a DFT-sleep terminal and a normal-sleep terminal. When one of the DFT-sleep terminal and the normal-sleep terminal is activated (logic high level), the isolation unit 41 enters the power-down mode.

For example, when the normal-sleep terminal receives the first logic level (i.e., logic low level) due to the voltage source (Vdd) is turned on, testers still can force the isolation unit 41 (so as the new isolation cell) operated in the power-down mode if the DFT-sleep terminal is set at the second logic level (i.e., logic high). Alternatively, the isolation unit 41 (so as the new isolation cell) can be operated in power-up mode if the DFT-sleep terminal is also set at the first logic level (i.e., logic low).

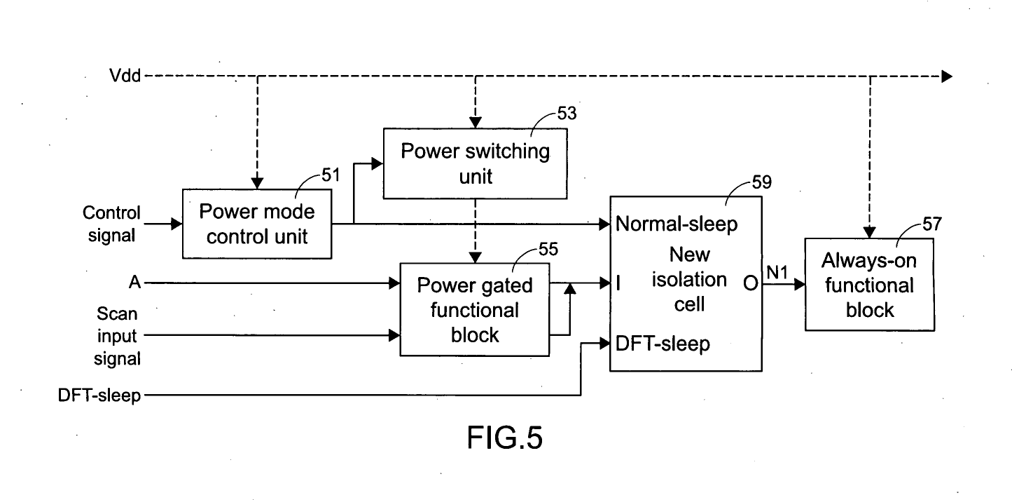

FIG. 5 is a block diagram showing the scan chain applying to a circuit having a new isolation cell of the present invention. Before the scan chain is executed to test the functions of the circuit, the voltage source (Vdd) in the circuit must be turned on.

In the circuit, the power mode control unit 51 receives the control signal and generates the normal-sleep signal to control power switching unit 53 and the new isolation cell 59. For example, when the normal-sleep signal is at the first logic level (logic low), it enters the power-up mode. In power-up mode, the power switching unit 53 can provide a source voltage (Vdd) to the power gated functional block 55. Also, the new isolation cell 59 functions as a buffer. In other words, the input signal (A) can be propagated to the power gated functional block 55 for processing, and the processed signal (N1) can be transmitted to the input terminal (I) of the new isolation cell 59 and the output terminal (O) of the new isolation cell 59 can output the processed signal (N1) to the always-on functional block 57.

Alternatively, when the normal-sleep signal is at a second logic level (logic high), it enters the power-down mode. In power-down mode, the power switching unit 53 stops providing the source voltage (Vdd) to the power gated functional block 55. Also, during the period of power-down mode, the new isolation cell 59 maintains at a specific logic level to the input terminal of the always-on functional block 57. In this way, the always-on functional block 57 can operate normally when the power gated functional block 55 is in power-down mode. Also, in power-down mode, the new isolation cell 59 is designed to output a specified logic level to the input terminal of the always-on functional block 57. There are three types of new isolation cell, which is dependent on the specific logic level of the new isolation cell. For example, the new isolation cell 59 can be designed to output a logic high to the input terminal of the always-on functional block 57; the new isolation cell 59 can be designed to output a logic low to the input terminal of the always-on functional block 57; or, the isolation cell 59 can be designed to output a logic level same as the previous logic level to the input terminal of the always-on functional block 57.

According to the embodiment of the present invention, when the circuit is in the scan mode, the normal-sleep signal controlled by the power mode control unit 51 has to be set at the first logic level (logic low). The scan input signal (test pattern) can be sequentially transmitted to the always-on functional block 57. Also, the scan output signal outputted by the always-on functional block 57 is the test result. When the new isolation cell 59 is intended to be test under the power-up mode, the DFT-sleep has to be controlled at the first logic level (logic low). On the contrary, when the new isolation cell 59 is intended to be test under the power-down mode, it is easy to set the DFT-sleep at the second logic level (logic high). Then, tester can execute the scan chain and the ATPG tool automatically generates scan tests to the circuit. Tester then analyzes the functions of the new isolation cell 59 operated in power-down mode.

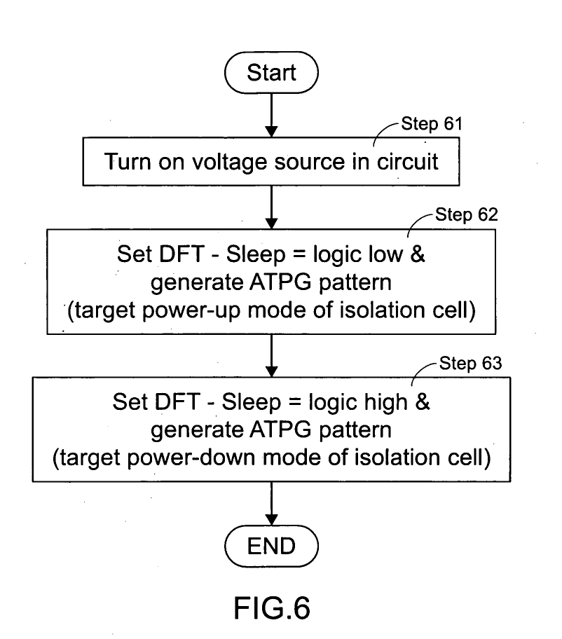

FIG. 6 is a flow chart showing the steps of testing the new isolation cell of the present invention operated in power-up mode and power-down mode by using a scan chain. At beginning, the voltage source (Vdd) has to be turned on (step 61). Testers can test the new isolation cell of the present invention operated in the power-up mode through setting the DFT-sleep terminal to logic low and executing the scan chain to generate the ATPG pattern (step 63). Accordingly, testers can test the new isolation cell of the present invention operated in the power-down mode by setting the DFT-sleep terminal to logic high and executing the scan chain to generate the ATPG pattern (step 65).

Therefore, without complicate circuit design in the isolation cell of the present invention, the isolation cell's behavior in the power-down mode can be tested by the scan chain, so as the testing quality is enhanced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An isolation cell having a test mode, connected between a first block and a second block, wherein the first block can operate in either a power-up mode or a power-down mode, comprising:
an input terminal for receiving an input signal that is derived from the first block;
an output terminal for outputting an output signal to the second block;
a normal-sleep terminal for determining the isolation cell is operated in the power-up mode or in the power-down mode, and the logic level of the normal-sleep terminal is determined by the operation mode of the first block; and
a DFT-sleep terminal is for overwriting the logic level of the normal-sleep terminal when the isolation cell is in the test mode.

2. The isolation cell having a test mode according to claim 1, wherein the normal-sleep terminal is at a first logic level if the first block is operated in the power-up mode; the normal-sleep terminal is at a second logic level if the first block is operated in the power-down mode.

3. The isolation cell having a test mode according to claim 1, wherein the normal-sleep terminal is always at a first logic level and the first block is always operated in the power-up mode if the isolation cell is in the test mode.

4. The isolation cell having a test mode according to claim 1, wherein the logic level of the output signal is same as that of the input signal when the isolation cell is operated in the power-up mode; the logic level of the output signal is at a predefined state when the isolation cell is operated in the power-down mode.

5. An isolation cell having a test mode, connected between a first block and a second block, wherein the first block can operate in either a power-up mode and a power-down mode, comprising:
an isolation unit having a sleep terminal, an input terminal, and an output terminal, wherein the sleep terminal is for determining the isolation unit is operated in the power-up mode or the power-down mode, the input terminal is for receiving an input signal which is derived from the first block, and the output terminal is for outputting an output signal to the second block; and
an OR-gate having a normal-sleep input terminal, a DFT-sleep input terminal, and an OR-gate output terminal connected to the sleep terminal;
wherein the normal-sleep terminal is at a first logic level if the first block is operated in the power-up mode; the normal-sleep terminal is at a second logic level if the first block is operated in the power-down mode; and the normal-sleep terminal is always at the first logic level and the first block is always operated in the power-up mode if the isolation cell is in the test mode.

6. The isolation cell having a test mode according to claim 5, wherein the first logic level is the logic low state; the second logic level is the logic high state.
